(19) United States
(12) Patent Application Publication
(10) Pub. No.: US 2022/0250268 A1
(43) Pub. Date: Aug. 11, 2022

(54) BLADE FIXTURE AND BLADE MOUNTER

(71) Applicant: DISCO CORPORATION, Tokyo (JP)

(72) Inventor: Masanori MISAIZU, Tokyo (JP)

(21) Appl. No.: 17/648,706

(22) Filed: Jan. 24, 2022

(30) Foreign Application Priority Data
Feb. 5, 2021 (JP) 2021-017074

(51) Int. Cl. B26D 1/143

(52) U.S. Cl. CPC B26D 1/143

(57) ABSTRACT

Provided is a blade fixture for fixing an annular cutting blade that has an opening portion and is used in a state of being supplied with a cutting liquid to a mount flange including a cylindrical boss portion having a screw thread disposed on an outer peripheral surface thereof. The blade fixture includes an annular nut that has an opening portion into which the boss portion is inserted and has a screw thread disposed on an inner circumferential surface of the opening portion, the screw thread corresponding to the screw thread of the boss portion. The blade fixture further includes a disk-shaped cutting liquid return plate that has an opening portion into which the boss portion is inserted and has an outside diameter larger than that of the nut.

### BACKGROUND OF THE INVENTION

### Field of the Invention

The present invention relates to a blade fixture for fixing an annular cutting blade to a mount flange and a blade mounter including the blade fixture.

### Description of the Related Art

A cutting apparatus having an annular cutting blade fitted to a spindle, for example, is used to process a plate-shaped workpiece typified by a semiconductor wafer. When the cutting blade and the workpiece are moved relative to each other while the cutting blade being rotated at high speed is made to cut into the workpiece, cutting processing (cutting) of the workpiece can be performed along a path of this movement.

Incidentally, when the rotated cutting blade is made to cut into the workpiece, the workpiece is cut, and a large amount of waste (cutting waste) is produced. When the cutting waste adheres to the workpiece, a defect tends occur in devices provided to the workpiece or the like. In addition, when the cutting waste is fixed to the workpiece, the cutting waste cannot be easily removed from the workpiece even if the workpiece is cleaned afterward.

Accordingly, when the workpiece is cut, the produced cutting waste is made to be washed away immediately by providing a liquid (cutting liquid) such as pure water to the cutting blade and the workpiece. In recent years, a cutting blade has been proposed which is integrally provided with a plate-shaped structure that can increase the amount of the cutting liquid supplied to the workpiece by efficiently dropping the cutting liquid supplied to the cutting blade in order to enhance an effect of cleaning by the cutting liquid (see Japanese Patent Laid-Open No. 2018-148177, for example).

### SUMMARY OF THE INVENTION

However, when the cutting blade is integrally provided with the plate-shaped structure as described above, cost involved in manufacturing the cutting blade is increased, and therefore, the cost of the cutting blade is increased. The cutting blade is what is generally called an expendable item, and is replaced frequently. Thus, an increase in the cost of the cutting blade greatly increases the cost of processing of the workpiece.

It is accordingly an object of the present invention to provide a blade fixture and a blade mounter that make it possible to increase the amount of cutting liquid supplied to a workpiece while holding down cost involved in manufacturing a cutting blade as an expendable item.

In accordance with an aspect of the present invention, there is provided a blade fixture for fixing an annular cutting blade that has an opening portion and is used in a state of being supplied with a cutting liquid to a mount flange including a cylindrical boss portion having a screw thread disposed on an outer peripheral surface thereof. The blade fixture includes an annular nut that has an opening portion into which the boss portion is inserted and has a screw thread disposed on an inner circumferential surface of the opening portion, the screw thread corresponding to the screw thread of the boss portion. The blade fixture further includes a disk-shaped cutting liquid return plate that has an opening portion into which the boss portion is inserted and has an outside diameter larger than that of the nut. The cutting blade is fixed to the mount flange by inserting the boss portion into the opening portion of the cutting liquid return plate and the opening portion of the nut such that the cutting liquid return plate is disposed on the cutting blade side in a state in which the boss portion is inserted in the opening portion of the cutting blade. Preferably, the nut and the cutting liquid return plate are formed integrally with each other.

In accordance with another aspect of the present invention, there is provided a blade mounter for fitting a spindle with an annular cutting blade that has an opening portion and is used in a state of being supplied with a cutting liquid. The blade mounter includes a mount flange, an annular nut, and a disk-shaped cutting liquid return plate. The mount flange includes a disk-shaped flange portion and a cylindrical boss portion that projects from one surface of the flange portion and has a screw thread disposed on an outer peripheral surface thereof. The mount flange is fitted to the spindle from another surface side of the flange portion. The annular nut has an opening portion into which the boss portion is inserted and has a screw thread disposed on an inner circumferential surface of the opening portion, the screw thread corresponding to the screw thread of the boss portion. The disk-shaped cutting liquid return plate has an opening portion into which the boss portion is inserted and has an outside diameter larger than that of the nut. The cutting blade is sandwiched and fixed between the nut and the flange portion by inserting the boss portion into the opening portion of the cutting liquid return plate and the opening portion of the nut such that the cutting liquid return plate is disposed on the cutting blade side in a state in which the boss portion is inserted in the opening portion of the cutting blade. Preferably, the nut and the cutting liquid return plate are formed integrally with each other.

The blade fixture according to one aspect of the present invention and the blade mounter according to another aspect of the present invention both include an annular nut and a disk-shaped cutting liquid return plate having an outside diameter larger than that of the nut. It is therefore not necessary to provide a plate-shaped structure to a cutting blade as an expendable item. Hence, according to the present invention, it is possible to increase the amount of cutting liquid supplied to a workpiece while holding down cost involved in manufacturing the cutting blade as an expendable item.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view schematically depicting a structure of a cutting apparatus;

FIG. 2 is an exploded perspective view schematically depicting a structure of a cutting unit;

FIG. 3 is a front view schematically depicting functions of a cutting liquid return plate;

FIG. 4 is a side view schematically depicting the functions of the cutting liquid return plate; and

FIG. 5 is an exploded perspective view schematically depicting a structure of a cutting unit according to a modification.

### DETAILED DESCRIPTION OF THE PREFERRED EMBODIMENT

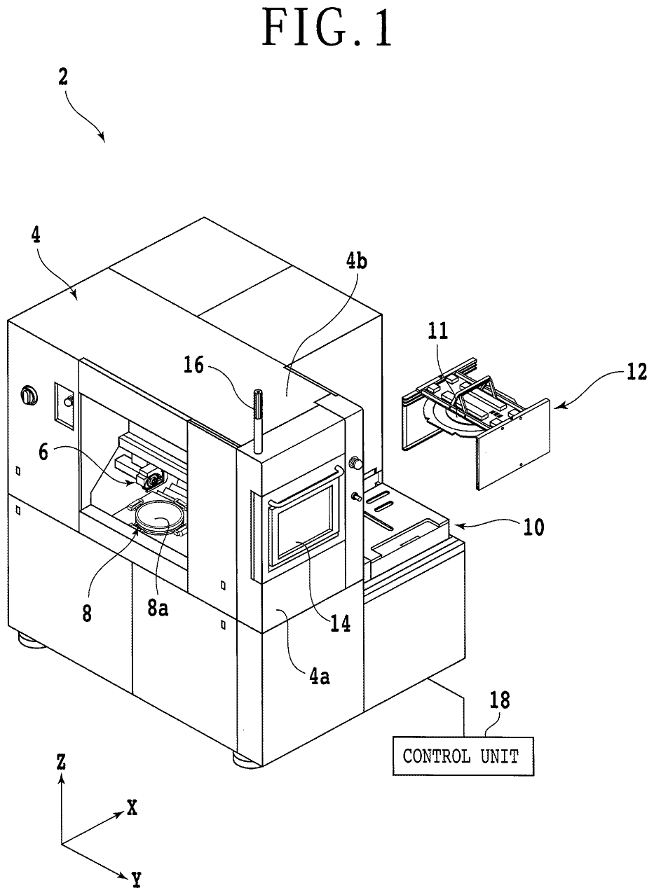

An embodiment of the present invention will hereinafter be described with reference to the accompanying drawings. FIG. 1 is a perspective view schematically depicting a cutting apparatus 2 in which a blade fixture according to the present embodiment is used. Incidentally, in FIG. 1, a part of elements constituting the cutting apparatus 2 is represented by a functional block. In addition, an X-axis direction (processing feed direction), a Y-axis direction (indexing feed direction), and a Z-axis direction (cutting feed direction) used in the following description are perpendicular to each other.

The cutting apparatus 2 has a frame (not depicted) that supports each element. As depicted in FIG. 1, this frame is covered by a cover 4. A space for cutting a plate-shaped workpiece 11 is formed on an inside of the frame and the cover 4. A cutting unit 6 is housed within this space. The cutting unit 6 is supported by a cutting unit moving mechanism (not depicted). This cutting unit moving mechanism moves the cutting unit 6 in the Y-axis direction and the Z-axis direction.

The workpiece 11 is typically a disk-shaped wafer formed with use of a semiconductor such as silicon. A top surface of the workpiece 11 is, for example, demarcated into a plurality of regions by planned dividing lines (streets) set in a lattice manner. A device such as an integrated circuit (IC) is formed in each of the regions.

However, the material, shape, structure, size, and the like of the workpiece 11 are not limited. For example, a substrate formed with use of another semiconductor, a ceramic, a resin, a metal, or the like can be used as the workpiece 11. Similarly, the kind, quantity, shape, structure, size, arrangement, and the like of the devices are not limited either. There may be a case in which no device is formed on the workpiece 11.

A chuck table 8 that can hold the workpiece 11 is disposed below the cutting unit 6. The chuck table 8 is coupled to a chuck table rotating mechanism (not depicted) including a motor. The chuck table rotating mechanism rotates the chuck table 8 about a rotational axis substantially parallel with the Z-axis direction. In addition, the chuck table 8 is supported by a chuck table moving mechanism (not depicted). The chuck table moving mechanism moves the chuck table 8 in the X-axis direction.

A part of an upper surface of the chuck table 8 is formed by a porous material, for example, and functions as a holding surface 8a that holds the workpiece 11. The holding surface 8a is substantially parallel with the X-axis direction and the Y-axis direction. The holding surface 8a is connected to a suction source (not depicted) via a suction passage (not depicted) or the like formed within the chuck table 8. When a negative pressure of the suction source is made to act in a state in which the workpiece 11 is placed on the holding surface 8a, the workpiece 11 is sucked by the holding surface 8a.

A cassette support base 10 is provided on an outside of the frame and the cover 4. A cassette 12 that can house workpieces 11 at respective positions of a plurality of different heights (positions in the Z-axis direction) is mounted on an upper surface of the cassette support base 10. A height of the cassette support base 10 is controlled by a cassette raising and lowering mechanism (not depicted) when, for example, the workpiece 11 is delivered from the cassette 12 to the space on the inside of the cover 4, or the workpiece 11 is delivered from the space on the inside of the cover 4 to the cassette 12.

A touch screen (a display device and an input device) 14 serving as a user interface is disposed on a front surface 4a of the cover 4. In addition, an indicator lamp 16 is disposed on an upper surface 4b of the cover 4. The touch screen 14 and the indicator lamp 16 are connected to a control unit 18 together with the cutting unit 6, the cutting unit moving mechanism, the chuck table rotating mechanism, the chuck table moving mechanism, the cassette raising and lowering mechanism, and the like described above.

The control unit 18 is, for example, constituted by a computer including a processing device and a storage device. The control unit 18 controls the plurality of elements described above according to a series of processing steps necessary for cutting the workpiece 11. The processing device is typically a central processing unit (CPU). The processing device performs various kinds of processing necessary to control the elements.

The storage device, for example, includes a main storage device such as a dynamic random access memory (DRAM) and an auxiliary storage device such as a hard disk drive or a flash memory. Functions of the control unit 18 are, for example, implemented by operation of the processing device according to software stored in the storage device. However, the functions of the control unit 18 may be implemented by only hardware.

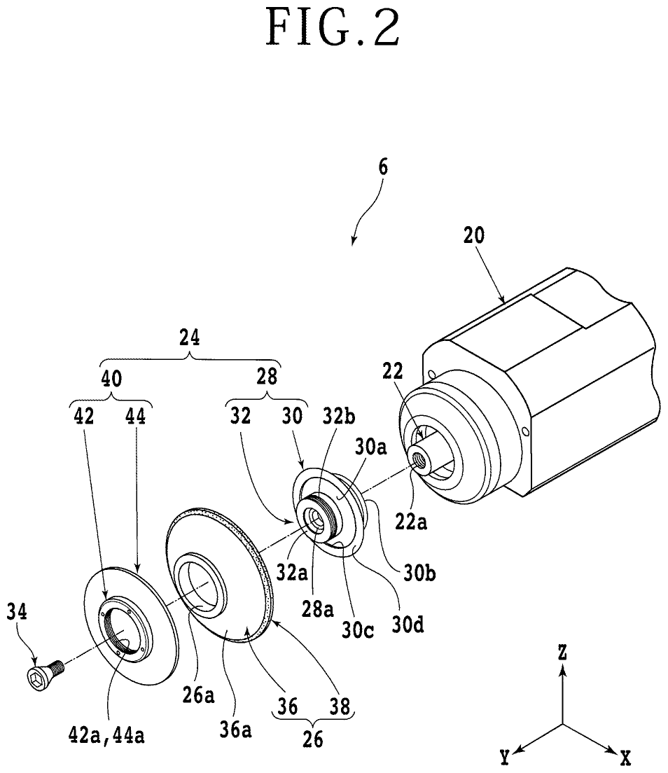

FIG. 2 is an exploded perspective view schematically depicting a structure of the cutting unit 6. The cutting unit 6 includes a tubular housing 20. The housing 20 houses a cylindrical spindle 22 as a rotary shaft substantially parallel with the Y-axis direction. A distal end portion (one end side) of the spindle 22 is exposed to an outside of the housing 20. A distal end surface of the distal end portion of the spindle 22 is provided with a threaded hole 22a. In addition, a rotating mechanism (not depicted) including a motor is coupled to a proximal end portion (another end side) of the spindle 22.

The distal end portion of the spindle 22 is fitted with an annular cutting blade 26 via a blade mounter 24. The blade mounter 24 includes a mount flange 28 attached to the distal end portion of the spindle 22. The mount flange 28 includes a disk-shaped flange portion 30 that supports the cutting blade 26 and a cylindrical boss portion 32 that projects from a central portion of a circular front surface (one surface) 30a of the flange portion 30.

Formed in the mount flange 28 is a through hole 28a that penetrates a central portion of the flange portion 30 from the front surface 30a side to a back surface (another surface) 30b side and penetrates a central portion of the boss portion 32 from a distal end 32a side to a proximal end side (flange portion 30 side). When the distal end portion of the spindle 22 is inserted into the through hole 28a from the back surface 30b side of the flange portion 30, the mount flange 28 is fitted to the spindle 22 from the back surface 30b side of the flange portion 30.

The through hole 28a is provided with an annular receiving portion that receives the head of a screw 34. Hence, when the screw 34 is inserted into the through hole 28a from the distal end 32a side of the boss portion 32 and the screw 34 is fastened to the threaded hole 22a of the spindle 22 via the through hole 28a, the mount flange 28 is fixed to the distal end portion of the spindle 22.

An outer circumferential portion on the front surface 30a side of the flange portion 30 is provided with an annular protruding portion 30c that slightly protrudes in a direction intersecting the front surface 30a (typically in a direction perpendicular to the front surface 30a). A distal end surface 30d of the protruding portion 30c is formed substantially flat. A region on the distal end 32a side of an outer peripheral surface 32b of the boss portion 32 is provided with a screw thread.

The cutting blade 26 is, for example, what is generally called a hub type cutting blade that integrally includes a base 36 formed of a metal or the like and having a shape of a circular truncated cone and an annular cutting edge 38 provided along an outer peripheral edge of the base 36. A central portion of the cutting blade 26 (central portion of the base 36) is provided with an opening portion 26a that penetrates the cutting blade 26 (base 36) in a thickness direction. The boss portion 32 is inserted into the opening portion 26a when the cutting blade 26 is attached to the mount flange 28.

The base 36 has a curved surface (first surface) 36a corresponding to the side surface of the circular truncated cone and a flat surface (second surface) (not depicted) corresponding to the bottom surface of the circular truncated cone and located substantially on an opposite side from the curved surface 36a. When the cutting blade 26 is attached to the mount flange 28, the boss portion 32 is inserted into the opening portion 26a such that the flat surface of the base 36 comes into contact with the distal end surface 30d of the flange portion 30. The cutting edge 38, for example, has a structure obtained by fixing abrasive grains formed of diamond or the like by a binder containing a metal such as nickel.

The blade mounter 24 further includes a blade fixture 40 used to fix the annular cutting blade 26 to the mount flange 28. The blade fixture 40, for example, includes an annular nut (nut portion) 42 and a disk-shaped cutting liquid return plate (cutting liquid return portion) 44 having an outside diameter (diameter) larger than an outside diameter (diameter) of the nut 42 and smaller than an outside diameter (diameter) of the cutting blade 26. The nut 42 and the cutting liquid return plate 44 are formed integrally with each other.

A central portion of the nut 42 is provided with an opening portion 42a into which the boss portion 32 of the mount flange 28 is inserted. A screw thread corresponding to the screw thread of the boss portion 32 is formed on an inner circumferential surface of the opening portion 42a. Similarly, an opening portion 44a into which the boss portion 32 is inserted is provided also to a central portion of the cutting liquid return plate 44. The opening portion 42a of the nut 42 and the opening portion 44a of the cutting liquid return plate 44 are connected to each other. Incidentally, a screw thread may be or may not be provided to an inner circumferential surface of the opening portion 44a.

When the cutting blade 26 is to be fixed to the mount flange 28, the boss portion 32 is inserted into the opening portion 42a of the nut 42 of the blade fixture 40 and the opening portion 44a of the cutting liquid return plate 44 in a state in which the boss portion 32 is inserted in the opening portion 26a of the cutting blade 26. An orientation of the blade fixture 40 is adjusted such that the cutting liquid return plate 44 is disposed on the cutting blade 26 side.

Then, the boss portion 32 is fastened to the blade fixture 40 by rotating the boss portion 32 and the blade fixture 40 relative to each other. Consequently, the cutting liquid return plate 44 side of the blade fixture 40 is in contact with the curved surface 36a side of the base 36 of the cutting blade 26, and the cutting blade 26 is sandwiched between the mount flange 28 and the blade fixture 40. That is, the cutting blade 26 is fixed in such a manner as to be sandwiched between the nut 42 and the flange portion 30.

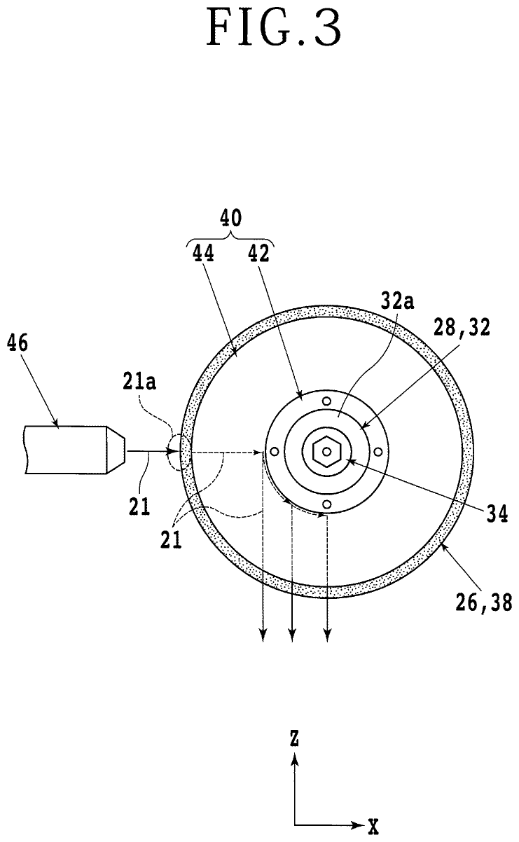

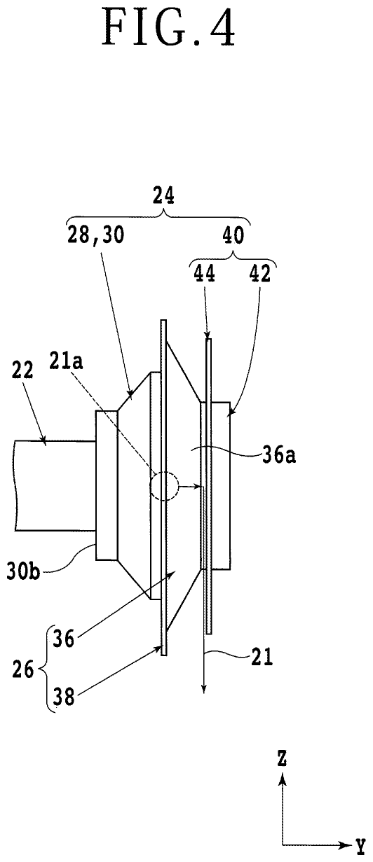

FIG. 3 is a front view schematically depicting functions of the cutting liquid return plate 44. FIG. 4 is a side view schematically depicting the functions of the cutting liquid return plate 44. The cutting unit 6 is provided with a blade cover that partially covers an outer circumferential portion of the cutting blade 26. As depicted in FIG. 3, a nozzle 46 that can supply a cutting liquid 21 to the outer circumferential portion of the cutting blade 26 is disposed on the blade cover.

As depicted in FIG. 3 and FIG. 4, for example, when the cutting liquid 21 is jetted from the nozzle 46 disposed on a side of the cutting blade 26 to a target area 21a located in the outer circumferential portion of the cutting blade 26, a part of the cutting liquid 21 flows on the curved surface 36a and goes toward the central portion of the cutting blade 26. In a case where the cutting liquid return plate 44 is not present, a large part of the cutting liquid 21 having reached the central portion of the cutting blade 26 is scattered to a front side of the cutting blade 26, and therefore, a sufficient amount of the cutting liquid 21 is not supplied to the vicinity of a processing point at which the cutting edge 38 of the cutting blade 26 and the workpiece 11 are in contact with each other.

On the other hand, the blade fixture 40 in the present embodiment includes, in addition to the nut 42, the disk-shaped cutting liquid return plate 44 having an outside diameter larger than that of the nut 42. Hence, the cutting liquid 21 having reached the central portion of the cutting blade 26 is bounced back by the cutting liquid return plate 44 and falls to the vicinity of the processing point. It is thereby possible to increase the amount of the cutting liquid 21 supplied to the vicinity of the processing point of the workpiece 11 and consequently prevent adhesion and fixation of a cutting waste to the workpiece 11.

As described above, the blade fixture 40 (and the blade mounter 24) in the present embodiment includes the annular nut 42 and the disk-shaped cutting liquid return plate 44 whose outside diameter is larger than that of the nut 42. It is therefore not necessary to provide a plate-shaped structure corresponding to the cutting liquid return plate 44 to the cutting blade 26 that is an expendable item. Hence, it is possible to increase the amount of the cutting liquid 21 supplied to the workpiece 11 while holding down cost involved in manufacturing the cutting blade 26 as an expendable item.

Further, in the present embodiment, the cutting liquid return plate 44 is separated from the cutting blade 26 that is an expendable item. Thus, the cutting liquid return plate 44 does not need to be discarded together with the cutting blade 26 as in a case where the cutting blade 26 and the cutting liquid return plate 44 are formed integrally with each other. That is, the cutting liquid return plate 44 can be used repeatedly.

It is to be noted that the present invention is not limited to the description of the foregoing embodiment and can be variously modified to be implemented. For example, the foregoing embodiment illustrates the blade fixture 40 integrally including the nut 42 and the cutting liquid return plate 44. However, the nut 42 and the cutting liquid return plate 44 may be separated from each other. In addition, an additional cutting liquid return plate may be provided to the back surface 30b side of the mount flange 28.

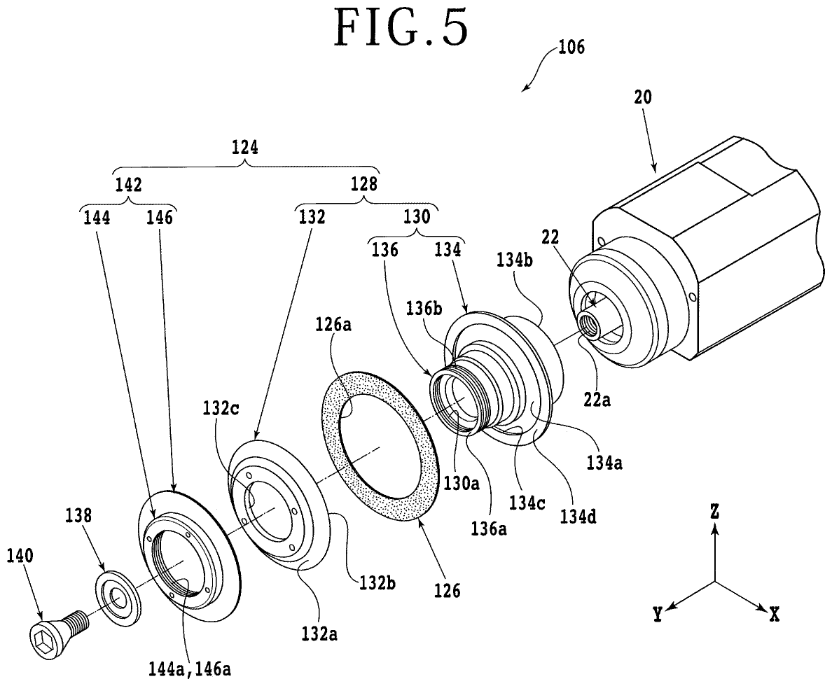

Further, the blade fixture according to the present invention can also be used to fix what is generally called a washer type cutting blade to the mount flange. FIG. 5 is an exploded perspective view schematically depicting a structure of a cutting unit 106 according to a modification. Incidentally, in the following, elements same as those in the cutting unit 6 in the foregoing embodiment are denoted by the same reference symbols, and detailed description thereof will be omitted.

The distal end portion of the spindle 22 is fitted with an annular cutting blade 126 via a blade mounter 124. The blade mounter 124 includes a mount flange 128 attached to the distal end portion of the spindle 22. The mount flange 128 includes a fixed mount 130 fixed to the distal end portion of the spindle 22 and a pressing flange 132 that presses the cutting blade 126 attached to the fixed mount 130.

The fixed mount 130 includes a disk-shaped flange portion 134 that supports the cutting blade 126 and a cylindrical boss portion 136 that projects from a central portion of a circular front surface (one surface) 134a of the flange portion 134. Formed in the fixed mount 130 is a through hole 130a that penetrates a central portion of the flange portion 134 from the front surface 134a side to a back surface (another surface) 134b side and penetrates a central portion of the boss portion 136 from a distal end 136a side to a proximal end side (flange portion 134 side).

The fixed mount 130 of the mount flange 128 is fitted to the spindle 22 from the back surface 134b side of the flange portion 134 by inserting the distal end portion of the spindle 22 into the through hole 130a from the back surface 134b side of the flange portion 134. The through hole 130a is provided with an annular receiving portion that receives a washer 138. Hence, when the washer 138 is disposed in the through hole 130a and a screw 140 is fastened to the threaded hole 22a of the spindle 22 via the washer 138, the fixed mount 130 is fixed to the distal end portion of the spindle 22.

An outer circumferential portion on the front surface 134a side of the flange portion 134 is provided with an annular protruding portion 134c that slightly protrudes in a direction intersecting the front surface 134a (typically in a direction perpendicular to the front surface 134a). A distal end surface 134d of the protruding portion 134c is formed substantially flat. A region on the distal end 136a side of an outer peripheral surface 136b of the boss portion 136 is provided with a screw thread.

The cutting blade 126 is a washer type cutting blade formed by an annular cutting edge having a structure obtained by fixing abrasive grains formed of diamond or the like by a binder such as a metal, a resin, or a ceramic. That is, a central portion of the cutting blade 126 is provided with a circular opening portion 126a that penetrates the cutting blade 126 in a thickness direction. When the cutting blade 126 is attached to the fixed mount 130, the boss portion 136 is inserted into the opening portion 126a such that one surface of the cutting blade 126 is brought into contact with the distal end surface 134d of the flange portion 134.

In a state in which the cutting blade 126 is attached to the fixed mount 130, the pressing flange 132 is attached to the fixed mount 130. The pressing flange 132 is, for example, formed in a shape of a circular truncated cone with use of a metal or the like. The pressing flange 132 has a curved surface (first surface) 132a corresponding to the side surface of the circular truncated cone and a flat surface (second surface) 132b corresponding to the bottom surface of the circular truncated cone and located substantially on an opposite side from the curved surface 132a.

A central portion of the pressing flange 132 is provided with an opening portion 132c that penetrates the pressing flange 132 in a thickness direction. When the pressing flange 132 is attached to the fixed mount 130, the boss portion 136 is inserted into the opening portion 132c. When the pressing flange 132 is further attached to the fixed mount 130 in a state in which the cutting blade 126 is attached to the fixed mount 130, the flat surface 132b of the pressing flange 132 comes into contact with another surface of the cutting blade 126.

The blade mounter 124 further includes a blade fixture 142 used to fix the annular cutting blade 126 to the mount flange 128. The blade fixture 142, for example, includes an annular nut (nut portion) 144 and a disk-shaped cutting liquid return plate (cutting liquid return portion) 146 having an outside diameter (diameter) larger than an outside diameter (diameter) of the nut 144 and smaller than an outside diameter (diameter) of the cutting blade 126. The nut 144 and the cutting liquid return plate 146 are formed integrally with each other.

A central portion of the nut 144 is provided with an opening portion 144a into which the boss portion 136 of the fixed mount 130 is inserted. A screw thread corresponding to the screw thread of the boss portion 136 is formed on an inner circumferential surface of the opening portion 144a. Similarly, an opening portion 146a into which the boss portion 136 is inserted is provided also to a central portion of the cutting liquid return plate 146. The opening portion 144a of the nut 144 and the opening portion 146a of the cutting liquid return plate 146 are connected to each other. Incidentally, a screw thread may be or may not be provided to an inner circumferential surface of the opening portion 146a.

When the cutting blade 126 is to be fixed to the mount flange 128, the boss portion 136 is inserted into the opening portion 144a of the nut 144 of the blade fixture 142 and the opening portion 146a of the cutting liquid return plate 146 in a state in which the boss portion 136 is inserted in the opening portion 126a of the cutting blade 126 and the opening portion 132c of the pressing flange 132. An orientation of the blade fixture 142 is adjusted such that the cutting liquid return plate 146 is disposed on the cutting blade 126 side (pressing flange 132 side).

Then, the boss portion 136 is fastened to the blade fixture 142 by rotating the boss portion 136 and the blade fixture 142 relative to each other. Consequently, the cutting liquid return plate 146 side of the blade fixture 142 is in contact with the curved surface 132a side of the pressing flange 132, and the cutting blade 126 is sandwiched between the fixed mount 130 and the pressing flange 132. That is, the cutting blade 126 is fixed in such a manner as to be sandwiched between the nut 144 and the flange portion 134.

Incidentally, in the blade fixture 142, the nut 144 and the cutting liquid return plate 146 may be separated from each other. In addition, an additional cutting liquid return plate may be provided to the back surface 134b side of the fixed mount 130.

Besides, structures, methods, and the like according to the foregoing embodiment and the modification can be modified to be implemented as appropriate without departing from the objective scope of the present invention.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A blade fixture for fixing an annular cutting blade that has an opening portion and is used in a state of being supplied with a cutting liquid to a mount flange including a cylindrical boss portion having a screw thread disposed on an outer peripheral surface thereof, the blade fixture comprising:
an annular nut that has an opening portion into which the boss portion is inserted and has a screw thread disposed on an inner circumferential surface of the opening portion, the screw thread corresponding to the screw thread of the boss portion; and
a disk-shaped cutting liquid return plate that has an opening portion into which the boss portion is inserted and has an outside diameter larger than that of the nut;
the cutting blade being fixed to the mount flange by inserting the boss portion into the opening portion of the cutting liquid return plate and the opening portion of the nut such that the cutting liquid return plate is disposed on the cutting blade side in a state in which the boss portion is inserted in the opening portion of the cutting blade.

2. The blade fixture according to claim 1, wherein
the nut and the cutting liquid return plate are formed integrally with each other.

3. A blade mounter for fitting a spindle with an annular cutting blade that has an opening portion and is used in a state of being supplied with a cutting liquid, the blade mounter comprising:
a mount flange including a disk-shaped flange portion and a cylindrical boss portion that projects from one surface of the flange portion and has a screw thread disposed on an outer peripheral surface thereof, the mount flange being fitted to the spindle from another surface side of the flange portion;
an annular nut that has an opening portion into which the boss portion is inserted and has a screw thread disposed on an inner circumferential surface of the opening portion, the screw thread corresponding to the screw thread of the boss portion; and
a disk-shaped cutting liquid return plate that has an opening portion into which the boss portion is inserted and has an outside diameter larger than that of the nut;
the cutting blade being sandwiched and fixed between the nut and the flange portion by inserting the boss portion into the opening portion of the cutting liquid return plate and the opening portion of the nut such that the cutting liquid return plate is disposed on the cutting blade side in a state in which the boss portion is inserted in the opening portion of the cutting blade.

4. The blade mounter according to claim 3, wherein
the nut and the cutting liquid return plate are formed integrally with each other.
